(19) United States
(12) Patent Application Publication
(10) Pub. No.: US 2025/0203759 A1
(43) Pub. Date: Jun. 19, 2025

(54) RADIO FREQUENCY MODULE AND COMMUNICATION DEVICE

(71) Applicant: Murata Manufacturing Co., Ltd., Nagaokakyo-shi (JP)

(72) Inventors: Nanami YUMURA, Nagaokakyo-shi (JP); Yuusuke KISHI, Nagaokakyo-shi (JP); Shogo YANASE, Nagaokakyo-shi (JP); Masaki TADA, Nagaokakyo-shi (JP); Ryoya SHIOMI, Nagaokakyo-shi (JP); Mizuki KINOSHITA, Nagaokakyo-shi (JP); Takanori UEJIMA, Nagaokakyo-shi (JP)

(73) Assignee: Murata Manufacturing Co., Ltd., Nagaokakyo-shi (JP)

(21) Appl. No.: 18/898,754

(22) Filed: Sep. 27, 2024

(30) Foreign Application Priority Data
Dec. 18, 2023 (JP) 2023-213139

(51) Int. Cl. H05K 1/02; H04B 1/40

(52) U.S. Cl. CPC H05K 1/0243; H05K 1/0216; H04B 1/40; H05K 2201/10098

(57) ABSTRACT

A radio frequency module includes a mounting board, a first component, and a shielding member. The mounting board has a first main surface and a second main surface. The first component is disposed on the first main surface of the mounting board. The shielding member is disposed on the first main surface of the mounting board. The first component is in contact with the shielding member.

### CROSS-REFERENCE TO RELATED APPLICATION

This application claims priority to Japanese Patent Application No. JP 2023-213139 filed on Dec. 18, 2023. The entire contents of the above-identified applications, including the specifications, drawings and claims, are incorporated herein by reference in their entirety.

### BACKGROUND OF THE DISCLOSURE

### 1. Field of the Disclosure

The present disclosure relates to a radio frequency module and a communication device and, more particularly, to a radio frequency module including a shielding member and a communication device including the radio frequency module.

### 2. Description of the Related Art

International Publication No. 2022/034869 discloses a radio frequency module having a transmission path and a reception path. The radio frequency module disclosed in International Publication No. 2022/034869 includes a module board (mounting board) and a metal shielding layer (shielding member) on a main surface of the module board. In the radio frequency module disclosed in International Publication No. 2022/034869, the metal shielding layer is disposed between an inductor in the transmission path and an inductor in the reception path.

### SUMMARY OF THE DISCLOSURE

However, in the radio frequency module disclosed in International Publication No. 2022/034869, the radio frequency module may become larger due to because the module board is larger.

An object of the present disclosure is to provide a downsized radio frequency module including a downsized mounting board and a communication device including the radio frequency module.

A radio frequency module according to an aspect of the present disclosure includes a board, a first component, and a shielding member. The mounting board has a first main surface and a second main surface. The first component is disposed on the first main surface of the mounting board. The shielding member is disposed on the first main surface of the mounting board. The first component is in contact with the shielding member.

A communication device according to an aspect of the present disclosure includes the radio frequency module and a signal processing circuit connected to the radio frequency module.

In the radio frequency module according to the aspect and the communication device according to the aspect, the radio frequency module can be downsized.

### BRIEF DESCRIPTION OF THE DRAWINGS

FIG. 1 is an end view of a radio frequency module according to a first embodiment;

FIG. 2 is a partial plan view of the radio frequency module described above;

FIG. 3 is a partial end view of the radio frequency module described above taken along line X1-X1 in FIG. 2;

FIG. 4 is a circuit structure diagram of a communication device including the radio frequency module described above;

FIG. 5 is a partial plan view of a radio frequency module according to a second embodiment;

FIG. 6 is a partial end view of the radio frequency module described above taken along line X2-X2 in FIG. 5;

FIG. 7 is a partial end view of the radio frequency module described above;

FIG. 8 is an end view of a radio frequency module according to a fourth embodiment;

FIG. 9 is an end view of a radio frequency module according to a sixth embodiment;

FIG. 10 is an end view of a radio frequency module according to a seventh embodiment;

FIG. 11 is an end view of an example of a radio frequency module according to an eighth embodiment; and

FIG. 12 is an end view of an example that differs from the example of the radio frequency module according to the eighth embodiment in the FIG. 11.

### DESCRIPTION OF THE EMBODIMENTS

Radio frequency modules and communication devices according to embodiments will be described with reference to the drawings. The drawings referenced in the following embodiments are schematic, and the ratios of the sizes and the thicknesses of components in the drawings may not necessarily reflect actual dimensional ratios.

### First Embodiment

### 1 Radio Frequency Module

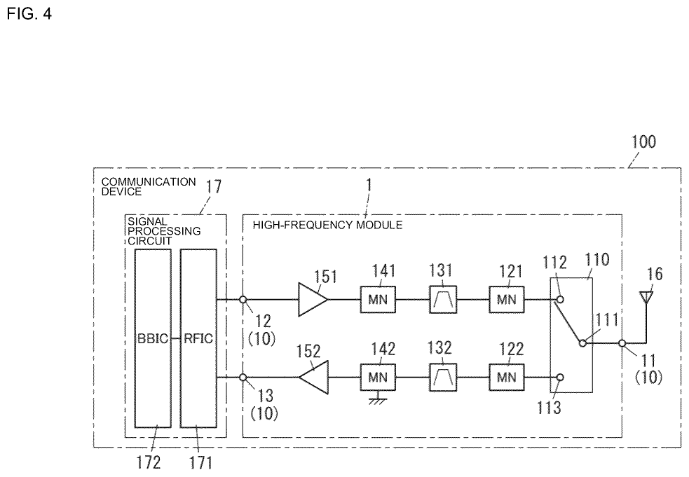

A radio frequency module 1 is used in, for example, a communication device 100, as illustrated in FIG. 4. The communication device 100 is, a mobile phone such as, for example, a smartphone. It may be noted that the communication device 100 is not limited to a mobile phone and may also be a wearable terminal, such as a smartwatch. The radio frequency module 1 supports, for example, 4G (4th generation mobile communication) standards, 5G (5th generation mobile communication) standards, and the like. 4G standards include, for example, the 3GPP (registered trademark, third generation partnership project) LTE (registered trademark, long-term evolution) standard. 5G standards include, for example, 5G NR (new radio). The radio frequency module 1 supports, for example, carrier aggregation and dual connectivity.

### 2 Circuit Structure of Radio frequency Module

The circuit structure of the radio frequency module 1 according to a first embodiment will be described with reference to FIG. 4.

As illustrated in FIG. 4, the radio frequency module 1 according to the first embodiment includes a plurality of external connection terminals 10, a switch 110, a first matching circuit 121, a second matching circuit 122, a transmission filter 131, a reception filter 132, a third matching circuit 141, a fourth matching circuit 142, a power amplifier 151, and a low-noise amplifier 152. The plurality of external connection terminals 10 include an antenna terminal 11, a signal output terminal 12, and a signal input terminal 13. The first matching circuit 121, the transmission filter 131, the third matching circuit 141, and the power amplifier 151 of the radio frequency module 1 are included in a transmission path. The second matching circuit 122, the reception filter 132, the fourth matching circuit 142, and the low-noise amplifier 152 of the radio frequency module 1 are included in a reception path.

### 2.1 Power Amplifier

The power amplifier 151 amplifies transmission signals. The power amplifier 151 includes an input terminal (not illustrated) and an output terminal (not illustrated). The input terminal of the power amplifier 151 is connected to a signal processing circuit 17 via the signal output terminal 12. The output terminal of the power amplifier 151 is connected to the transmission filter 131 via the third matching circuit 141.

### 2.2 Transmission Filter

The transmission filter 131 is a filter through which transmission signals pass. The transmission filter 131 is an acoustic wave filter that includes, for example, a plurality of series arm resonators and a plurality of parallel arm resonators. An elastic wave filter is, for example, a SAW (surface acoustic wave) filter that uses elastic surface waves. The transmission filter 131 includes an input terminal (not illustrated) and an output terminal (not illustrated). The input terminal of the transmission filter 131 is connected to the output terminal of the power amplifier 151 via the third matching circuit 141. The output terminal of the transmission filter 131 is connected to the switch 110 via the first matching circuit 121.

### 2.3 Low-Noise Amplifier

The low-noise amplifier 152 amplifies reception signals. The low-noise amplifier 152 includes an input terminal (not illustrated) and an output terminal (not illustrated). The input terminal of the low-noise amplifier 152 is connected to the signal processing circuit 17 via the signal input terminal 13. The output terminal of the low-noise amplifier 152 is connected to the reception filter 132 via the fourth matching circuit 142.

### 2.4 Reception Filter

The reception filter 132 is a filter through which reception signals pass. The reception filter 132 is an acoustic wave filter that includes, for example, a plurality of series arm resonators and a plurality of parallel arm resonators. An acoustic wave filter is, for example, a SAW filter that uses surface acoustic waves. The reception filter 132 includes an input terminal (not illustrated) and an output terminal (not illustrated). The input terminal of the reception filter 132 is connected to the switch 110 via the second matching circuit 122. The output terminal of the reception filter 132 is connected to the output terminal of the low-noise amplifier 152 via the fourth matching circuit 142.

### 2.5 Switch

The switch 110 switches the filter connected to the antenna terminal 11 between the transmission filter 131 and the reception filter 132. That is, the switch 110 connects either the reception path or the transmission path to the antenna terminal 11. The switch 110 includes a common terminal 111 and a plurality of (two in the illustrated example) selection terminals 112 and 113. The common terminal 111 is connected to the antenna terminal 11. The selection terminal 112 is connected to the transmission filter 131 via the first matching circuit 121. The selection terminal 113 is connected to the reception filter 132 via the second matching circuit 122.

### 2.6 Matching Circuit

The first matching circuit 121 performs impedance matching between the output terminal of the transmission filter 131 and the selection terminal 112 of the switch 110. The first matching circuit 121 includes at least one of not less than one capacitor and not less than one inductor.

The second matching circuit 122 performs impedance matching between the selection terminal 113 of the switch 110 and the input terminal of the reception filter 132. The second matching circuit 122 includes at least one of not less than one capacitor and not less than one inductor.

The third matching circuit 141 performs impedance matching between the output terminal of the power amplifier 151 and the input terminal of the transmission filter 131. The third matching circuit 141 includes at least one of not less than one capacitor and not less than one inductor.

The fourth matching circuit 142 performs impedance matching between the output terminal of the reception filter 132 and the input terminal of the low-noise amplifier 152. The fourth matching circuit 142 includes at least one of not less than one capacitor and not less than one inductor. In addition, the fourth matching circuit 142 includes a capacitor connected to a ground electrode 23.

### 3 Structure of Radio frequency Module

The structure of the radio frequency module 1 according to the first embodiment will be described with reference to the drawings.

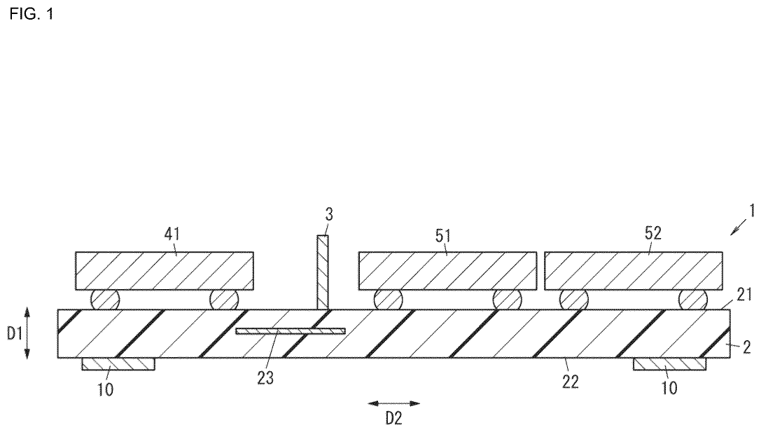

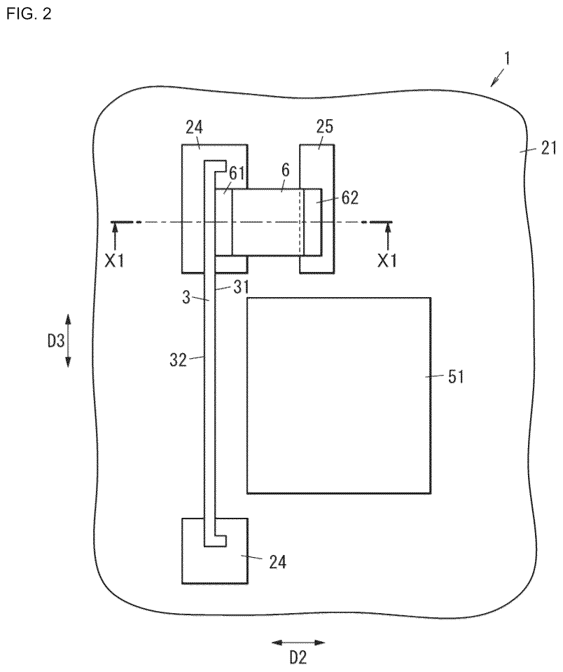

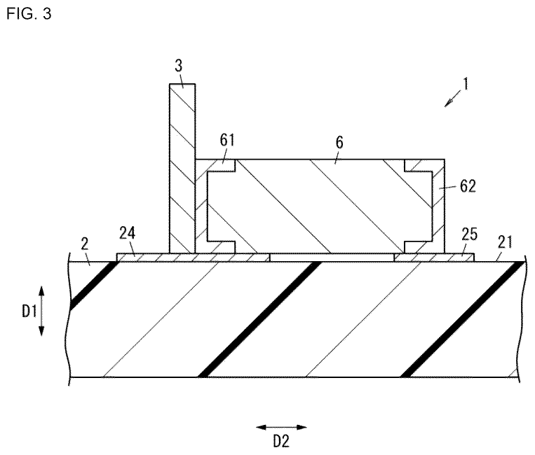

As illustrated in, for example, FIG. 1, the radio frequency module 1 according to the first embodiment includes a mounting board 2, a shielding member 3, an electronic component 41, an electronic component 51, an electronic component 52, and the external connection terminals 10. The radio frequency module 1 further includes an electronic component 6, as illustrated in FIGS. 2 and 3.

### 3.1 Mounting Board

The mounting board 2 has a first main surface 21 and a second main surface 22, as illustrated in FIG. 1. The first main surface 21 and the second main surface 22 face away from each other in a first direction D1.

The shielding member 3, the electronic component 41, the electronic component 51, the electronic component 52, and the electronic component 6 are disposed on the first main surface 21 of the mounting board 2.

The external connection terminals 10 are disposed on the second main surface 22 of the mounting board 2.

The mounting board 2 is a multilayer board that includes, for example, a plurality of dielectric layers and a plurality of conductive layers. The plurality of dielectric layers and the plurality of conductive layers are laminated together in the first direction D1. The plurality of conductive layers are formed in a predetermined pattern defined for each layer. Each of the plurality of conductive layers includes one or more conductor portions on one plane orthogonal to the first direction D1. The material of the conductive layers is, for example, copper. The plurality of conductive layers include the ground electrodes 23 that give a ground potential. In the radio frequency module 1, the plurality of ground terminals and the ground electrodes 23 are electrically connected to each other through via conductors of the mounting board 2 and the like. The mounting board 2 is, for example, a resin multilayer board. The mounting board 2 is not limited to a resin multilayer board and may also be a LTCC (low-temperature co-fired ceramics) board, a printed wiring board, or a HTCC (high-temperature co-fired ceramics) board. In addition, the ground electrode 23 may be formed on the first main surface 21 of the mounting board 2.

Furthermore, the mounting board 2 is not limited to a resin multilayer board and may also be a wiring structure. A wiring structure is, for example, a multilayer structure. A multilayer structure includes at least one insulating layer and at least one conductive layer. The insulating layer is formed in a predefined pattern. Assuming a plurality of insulating layers are present, each of the insulating layers is formed in a predetermined pattern defined for each of the layers. The conductive layer is formed in a predetermined pattern that differs from the predetermined pattern of the insulating layer. Assuming a plurality of conductive layers are present, each of the conductive layers is formed in a predetermined pattern defined for each of the layers. The conductive layer may include one or more rewiring portions. In the wiring structure, of the two surfaces facing away from each other in the thickness direction of the multilayer structure, a first surface is the first main surface 21 of the mounting board 2, and a second surface is the second main surface 22 of the mounting board 2. The wiring structure may be, for example, an interposer. The interposer may be an interposer including a silicon substrate or may be a multilayer board.

The first main surface 21 and the second main surface 22 of the mounting board 2 are apart from each other in the first direction D1 and intersect the first direction D1. The first main surface 21 of the mounting board 2 intersects, for example, the first direction D1, but a side surface of the conductor portion or the like may be included as a surface that does not intersect, for example, the first direction D1. In addition, the second main surface 22 of the mounting board 2 intersects, for example, the first direction D1, but a side surface of the conductor portion or the like may be included as a surface that does not intersect, for example, the first direction D1. Furthermore, the first main surface 21 and the second main surface 22 of the mounting board 2 may have fine irregularities, fine recessed portions, or fine raised portions.

### 3.2 Shielding Member

The shielding member 3 is disposed on the first main surface 21 of the mounting board 2, as illustrated in FIGS. 1 to 3. The shielding member 3 is disposed between the electronic component 41 and the electronic component 51, as illustrated in FIG. 1. Here, “the shielding member 3 is disposed between the electronic component 41 and the electronic component 51” may correspond to the shielding member 3 being disposed on a straight line that connects any position in the electronic component 41 and any position in the electronic component 51 to each other.

The shielding member 3 has conductivity. The shielding member 3 is connected to one or more (two in FIG. 2) land electrodes 24 disposed on the first main surface 21. More specifically, the shielding member 3 is connected to two land electrodes 24 via, for example, solder. The two land electrodes 24 are connected to the ground electrode 23. As a result, the shielding member 3 can improve isolation between the electronic component 41 and the electronic component 51.

The shielding member 3 has a short-axis direction that is equal to a direction D2 orthogonal to, for example, the first direction D1 and a long-axis direction that is equal to a direction D3 orthogonal to the first direction D1 and the direction D2. The shielding member 3 is, for example, a metal plate having a thickness direction that is equal to the direction D2. It may be noted that the shielding member 3 may have an L-shape, a U-shape, or a crank shape.

### 3.3 Electronic Component

The electronic component 41 is disposed on the first main surface 21 of the mounting board 2. The electronic component 41 includes elements included in the transmission path of the radio frequency module 1. The electronic component 41 is, for example, an IC chip including the power amplifier 151. The electronic component 41 corresponds to the second component in the present disclosure.

The electronic component 41 is, for example, flip-chip mounted on the first main surface 21 of the mounting board 2. The electronic component 41 is connected to the mounting board 2 via, for example, a plurality of conductive bumps. The material of the conductive bumps is, for example, solder, gold, or copper.

The electronic component 51 is disposed on the first main surface 21 of the mounting board 2. The electronic component 51 includes elements included in the reception path of the radio frequency module 1. Electronic component 51 is, for example, an IC chip including the low-noise amplifier 152. The electronic component 51 corresponds to the third component in the present disclosure.

The electronic component 51 is, for example, flip-chip mounted on the first main surface 21 of the mounting board 2. The electronic component 51 is connected to the mounting board 2 via, for example, a plurality of conductive bumps. The material of the conductive bumps is, for example, solder, gold, or copper.

The electronic component 52 is disposed on the first main surface 21 of the mounting board 2. The distance between the electronic component 52 and the electronic component 41 is longer than the distance between the electronic component 51 and the electronic component 41. The electronic component 52 is, for example, an IC chip including the switch 110.

The electronic component 52 is, for example, flip-chip mounted on the first main surface 21 of the mounting board 2. The electronic component 52 is connected to the mounting board 2 via, for example, a plurality of conductive bumps. The material of the conductive bumps is, for example, solder, gold, or copper.

The electronic component 6 is disposed on the first main surface 21 of the mounting board 2. The electronic component 6 includes elements included in the reception path of the radio frequency module 1 and is connected to the ground electrode 23. The electronic component 6 is, for example, a capacitor included in the fourth matching circuit 142.

The electronic component 6 is disposed in contact with the shielding member 3. The electronic component 6 corresponds to the first component in the present disclosure. Here, “the electronic component 6 is disposed in contact with the shielding member 3” is not restricted to the electronic component 6 and the shielding member 3 being in direct contact with each other but may also be understood that they are in contact with each other via solder or the like. This can reduce the mounting area of the electronic component 6 and the shielding member 3 on the first main surface 21 of the mounting board 2, and accordingly, reduce the area of the mounting board 2.

The electronic component 6 is, for example, a chip capacitor and includes a first electrode 61 and a second electrode 62. The shielding member 3 is in contact with the first electrode 61 of the electronic component 6. The first electrode 61 is connected to the land electrode 24 of the mounting board 2 via solder. That is, the first electrode 61 is connected to the mounting board 2. As a result, the first electrode 61 of the electronic component 6 is connected to the ground electrode 23 directly and via the shielding member 3. Accordingly, the potential difference between the first electrode 61 of the electronic component 6 and the shielding member 3 becomes zero, occurrence of parasitic capacitance is reduced, and the connectivity between the first electrode 61 of the electronic component 6 and the ground electrode 23 can be improved. The second electrode 62 is connected to the land electrode 25 disposed on the first main surface 21 of the mounting board 2 via solder.

### 3.4 External Connection Terminals

The plurality of external connection terminals 10 electrically connect the mounting board 2 and an external board to each other.

The plurality of external connection terminals 10 are disposed on the second main surface 22 of the mounting board 2, as illustrated in FIG. 1. Here, “the plurality of external connection terminals 10 are disposed on the second main surface 22 of the mounting board 2” may be understood as the external connection terminals 10 are mechanically connected to the second main surface 22 of the mounting board 2 and the external connection terminals 10 are electrically connected to an appropriate conductor portion of the mounting board 2. The material of the plurality of external connection terminals 10 is, for example, a metal, such as copper or copper alloy. The plurality of external connection terminals 10 are columnar electrodes. The columnar electrodes are joined to the conductor portion of the mounting board 2 via, for example, solder but not limited to this, and the columnar electrodes may also be joined via a conductive adhesive (for example, a conductive paste) or joined directly.

### 4 Communication Device

The communication device 100 includes the radio frequency module 1, the signal processing circuit 17, and an antenna 16, as illustrated in FIG. 4.

The antenna 16 is connected to the antenna terminal 11 of the radio frequency module 1. The antenna 16 has a transmission function that radiates a transmission signal output from the radio frequency module 1 as radio waves, and a reception function that receives a reception signal as radio waves from the outside and outputs the reception signal to the radio frequency module 1.

The signal processing circuit 17 includes an RF signal processing circuit 171 and a baseband signal processing circuit 172. The signal processing circuit 17 processes signals passing through the radio frequency module 1. More specifically, the signal processing circuit 17 processes transmission signals and reception signals.

The RF signal processing circuit 171 is, for example, an RFIC (radio frequency integrated circuit). The RF signal processing circuit 171 performs signal processing of radio frequency signals.

The RF signal processing circuit 171 performs signal processing, such as up-conversion, and amplification on the transmission signal transmitted from the baseband signal processing circuit 172 and outputs the transmission signal subjected to signal processing to the radio frequency module 1. In addition, the RF signal processing circuit 171 performs amplification and signal processing, such as up-conversion, on the reception signal output from the radio frequency module 1 and outputs the reception signal subjected to signal processing to the baseband signal processing circuit 172.

The baseband signal processing circuit 172 is, for example, a BBIC (baseband integrated circuit). The baseband signal processing circuit 172 performs predetermined signal processing on the transmission signal from the outside of the signal processing circuit 17. The reception signal processed by the baseband signal processing circuit 172 is used as, for example, an image signal for image display or an audio signal for conversation.

In addition, the RF signal processing circuit 171 also functions as a control unit that controls the connection of the switch 110 of the radio frequency module 1 in accordance with transmission and reception of radio frequency signals (transmission signal and reception signal). Specifically, the RF signal processing circuit 171 switches the connection of the switch 110 of the radio frequency module 1 depending on a control signal (not illustrated). Also, the control unit may be provided outside the RF signal processing circuit 171, for example, in the radio frequency module 1 or the baseband signal processing circuit 172.

### 5 Effects

The radio frequency module 1 according to the first embodiment includes the mounting board 2, the electronic component 6, and the shielding member 3. The mounting board 2 has the first main surface 21 and the second main surface 22. The electronic component 6 is disposed on the first main surface 21 of the mounting board 2. The shielding member 3 is disposed on the first main surface 21 of the mounting board 2. The electronic component 6 is in contact with the shielding member 3. As a result, in the radio frequency module 1 according to the first embodiment, since the electronic component 6 and the shielding member 3 can be disposed lose to each other in plan view in the first direction D1, the area of the mounting board 2 can be reduced. Accordingly, the radio frequency module 1 can be downsized.

In addition, in the radio frequency module 1 according to the first embodiment, the electronic component 6 includes the first electrode 61 connected to the mounting board 2. The shielding member 3 is in contact with the first electrode 61 of the electronic component 6. As a result, in the radio frequency module according to the first embodiment, deterioration of the characteristics of the radio frequency module due to the parasitic capacitance generated between the electronic component 6 and the shielding member 3 can be reduced.

In addition, in the radio frequency module 1 according to the first embodiment, the mounting board 2 includes the ground electrode 23. The first electrode 61 of the electronic component 6 is connected to the ground electrode 23. The shielding member 3 is in contact with the land electrode 24 of the mounting board 2 connected to the ground electrode 23.

As a result, in the radio frequency module 1 according to the first embodiment, the first electrode 61 of the electronic component 6 can be connected to the ground electrode 23 via the shielding member 3. Accordingly, the connectivity between the first electrode 61 of the electronic component 6 and the ground electrode 23 is improved.

In addition, the radio frequency module 1 according to the first embodiment includes the electronic component 41 and the electronic components 51 that are disposed on the first main surface 21 of the mounting board 2. The shielding member 3 is disposed between the electronic component 41 and the electronic component 51. At least one of the electronic component 41 and the electronic components 51 is the power amplifier 151 that amplifies the transmission signal. As a result, in the radio frequency module 1 according to the first embodiment, isolation between the electronic component 41 and the electronic component 51 is improved.

The communication device 100 according to the first embodiment includes the radio frequency module 1 and the signal processing circuit 17 connected to the radio frequency module 1. As a result, in the communication device 100 according to the first embodiment, downsizing and high integration of the communication device 100 can be achieved by downsizing the radio frequency module 1.

### Second Embodiment

### 1 Structure

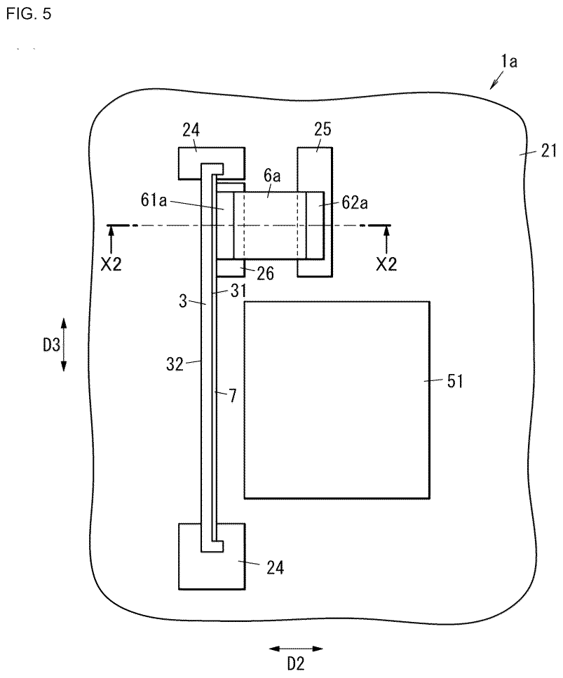

A radio frequency module 1a according to a second embodiment includes an electronic component 6a instead of the electronic component 6, as illustrated in FIG. 5. In the radio frequency module 1a according to the second embodiment, the shielding member 3 and the electronic component 6a are insulated from each other.

The electronic component 6a is, for example, a capacitor included in the fourth matching circuit 142. The electronic component 6a is, for example, a capacitor connected between the input terminal of the low-noise amplifier 152 and the output terminal of the reception filter 132.

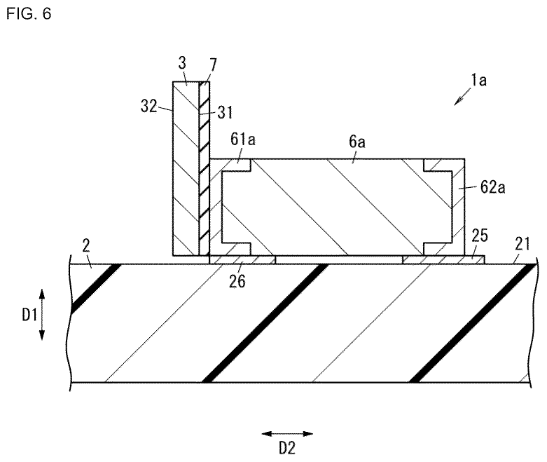

In the radio frequency module 1a according to the second embodiment, the insulator 7 is disposed on the shielding member 3, as illustrated in FIGS. 5 and 6. The shielding member 3 and the electronic component 6a are in contact with each other via the insulator 7. Here, “the shielding member 3 and the electronic component 6a are in contact with each other via the insulator 7” may be understood as the shielding member 3 and the electronic component 6a are not directly contact with each other, the shielding member 3 is in contact with the insulator 7, and the electronic component 6a is in contact with the insulator 7. Specifically, the main surface 31 of the shielding member 3 faces a first electrode 61a of the electronic component 6a in the direction D2, and the insulator 7 is disposed between the main surface 31 of the shielding member 3 and the first electrode 61a of the electronic component 6a.

As illustrated in FIGS. 5 and 6, the shielding member 3 has the main surface 31 and the main surface 32 that face away from each other in the direction D3. The main surface 31 of the shielding member 3 faces the electronic component 6. The insulator 7 is disposed on the main surface 31 of the shielding member 3. The insulator 7 is, for example, an epoxy resin. The insulator 7 is formed by applying, for example, a material including an epoxy resin to the shielding member 3.

As illustrated in FIGS. 5 and 6, the first electrode 61a of the electronic component 6a is connected to a land electrode 26 that differs from the land electrode 24 of the mounting board 2. In the mounting board 2, the land electrode 24 and the land electrode 26 are insulated from each other. Accordingly, the electronic component 6a is insulated from the shielding member 3 and the ground electrode 23. A second electrode 62a of the electronic component 6a is connected to a land electrode 25 that differs from the land electrode 24 of the mounting board 2.

In the radio frequency module 1a according to the second embodiment, the electronic component 6a is insulated from the ground electrode 23. Accordingly, a component that needs to be insulated from the ground electrode 23 can be used as the electronic component 6a. As a result, since the freedom of disposition of components on the first main surface 21 of the mounting board 2 is improved in the radio frequency module 1a according to the second embodiment, the radio frequency module 1a can be easily downsized.

It may be noted that, in the radio frequency module 1a according to the second embodiment, the insulator 7 may be further disposed on the main surface 32 of the shielding member 3.

### 2 Effects

In the radio frequency module 1a according to the second embodiment, the shielding member 3 has the main surface 31 facing the electronic component 6a. The insulator 7 is disposed on the main surface 31 of the shielding member 3. As a result, since the electronic component 6a and the shielding member 3 can be insulated from each other in the radio frequency module 1a according to the second embodiment, the electronic component 6a can be easily disposed in contact with the shielding member 3. Accordingly, the radio frequency module 1a can be easily downsized.

### Third Embodiment

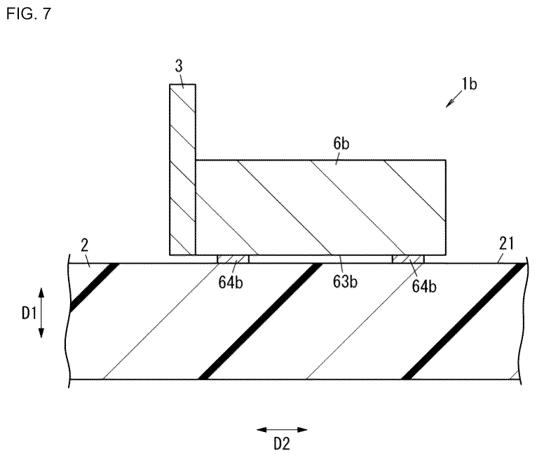

A radio frequency module 1b according to a third embodiment includes an electronic component 6b instead of the electronic component 6, as illustrated in FIG. 7. In the radio frequency module 1b according to the third embodiment, the shielding member 3 and the electronic component 6b are insulated from each other.

The electronic component 6b is an LGA (land grid array) element including connection terminals on a main surface 63b facing the first main surface 21 of the mounting board 2. The electronic component 6b includes a plurality of electrodes 64b on the main surface 63b. That is, as illustrated in FIG. 7, the plurality of electrodes 64b of the electronic component 6b are not in contact with the shielding member 3. Accordingly, the electronic component 6b is insulated from the shielding member 3 and the ground electrode 23. The electronic component 6b is, for example, the reception filter 132.

In the radio frequency module 1b according to the third embodiment, the electronic component 6b is insulated from the ground electrode 23. Accordingly, in the radio frequency module 1b according to the third embodiment, the electronic component 6b not connected to the ground electrode 23 can be brought into contact with the shielding member 3. As a result, since the freedom of disposition of components on the first main surface 21 of the mounting board 2 is improved in the radio frequency module 1b according to the third embodiment, the radio frequency module 1b can be downsized as the radio frequency module 1 according to the first embodiment.

### Fourth Embodiment

### 1 Structure

A radio frequency module 1c according to a fourth embodiment includes a resin layer 8 and an external shielding electrode 9 in addition to the structure of the radio frequency module 1 according to the first embodiment.

### (1.1) Resin Layer

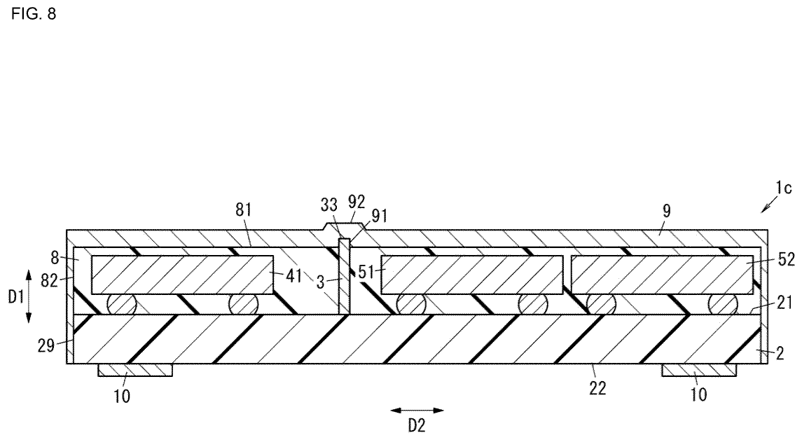

The resin layer 8 is disposed on the first main surface 21 of the mounting board 2, as illustrated in FIG. 8. The resin layer 8 covers the electronic component 6. In addition, the resin layer 8 covers the electronic component 41, the electronic component 51, and the electronic component 52, as illustrated in FIG. 8. The resin layer 8 includes, for example, an epoxy resin and a filler.

### 1.2 External Shielding Electrode

The external shielding electrode 9 covers the first main surface 21 of the mounting board 2. More specifically, the external shielding electrode 9 covers the resin layer 8. In the radio frequency module 1c, the external shielding electrode 9 serves as an electromagnetic shield between the inside and the outside of the radio frequency module 1c. The external shielding electrode 9 has a multilayer structure in which a plurality of metal layers are laminated together, but the external shielding electrode 9 may include a single metal layer instead of a multilayer structure. One metal layer includes one or more types of metal. The external shielding electrode 9 covers a main surface 81 of the resin layer 8 opposite to the mounting board 2, an outer peripheral surface 82 of the resin layer 8, and an outer peripheral surface 29 of the mounting board 2.

The external shielding electrode 9 is in contact with the shielding member 3. More specifically, the external shielding electrode 9 includes a recessed portion 91 facing the first main surface 21 of the mounting board 2. The external shielding electrode 9 has a raised portion 92 that overlaps the recessed portion 91 in plan view in the first direction D1. One end 33 not in contact with the mounting board 2 of two end portions of the shielding member 3 arranged in the first direction D1 is disposed in the recessed portion 91 of the external shielding electrode 9. That is, the shielding member 3 is in contact with the recessed portion 91 of the external shielding electrode 9. As a result, since the contact area between the external shielding electrode 9 and the shielding member 3 becomes larger, the external shielding electrode 9 and the ground electrode 23 are electrically connected to each other via the shielding member 3. Accordingly, the electromagnetic shielding effect of the external shielding electrode 9 is improved.

### 2 Effects

The radio frequency module 1c according to the fourth embodiment includes the external shielding electrode 9 that covers the first main surface 21 of the mounting board 2. The mounting board 2 includes the ground electrode 23 connected to a shielding member 3. The shielding member 3 is in contact with the external shielding electrode 9. As a result, in the radio frequency module 1c according to the fourth embodiment, the external shielding electrode 9 can be connected to the ground electrode 23 via the shielding member 3. Accordingly, the noise resistance of the radio frequency module 1c is improved.

In addition, in the radio frequency module 1c according to the fourth embodiment, the external shielding electrode 9 has the recessed portion 91 facing the first main surface 21 of the mounting board 2. The shielding member 3 is in contact with the recessed portion 91 of the external shielding electrode 9. As a result, since the contact area between the shielding member 3 and the external shielding electrode 9 is large in the radio frequency module 1c according to the fourth embodiment, the shielding performance of the external shielding electrode 9 is improved.

### Fifth Embodiment

### 1 Structure

The radio frequency module 1c according to a fifth embodiment includes the resin layer 8 and the external shielding electrode 9 as the radio frequency module 1c according to the fourth embodiment. In addition, the radio frequency module 1c according to the fifth embodiment further includes the insulator 7 as the radio frequency module 1a according to the second embodiment.

The material of the insulator 7 differs from the material of the resin layer 8. For example, the resin layer 8 includes a filler, and the insulator 7 does not include a filler. In addition, the resin material other than the filler of the resin layer 8 and the resin material of the insulator 7 differ from each other.

In the radio frequency module 1c according to the fifth embodiment, the shielding member 3 and the electronic component 6 are in contact with each other via the insulator 7 as the radio frequency module 1a according to the second embodiment. The resin layer 8 covers the electronic component 6 and the insulator 7. Specifically, the main surface 31 of the shielding member 3 faces the first electrode 61a of the electronic component 6a in the direction D2, and the insulator 7 is disposed between the main surface 31 of the shielding member 3 and the first electrode 61a of the electronic component 6a. The resin layer 8 is not present between the main surface 31 of the shielding member 3 and the first electrode 61a of the electronic component 6a.

### 2 Effects

The radio frequency module 1c according to the fifth embodiment further includes the resin layer 8 that covers the mounting board 2 and the electronic component 6a. The material of the insulator 7 differs from the material of the resin layer 8. At least a portion of the insulator 7 is located between the shielding member 3 and the electronic component 6a. As a result, in the radio frequency module 1c according to the fifth embodiment, the electronic component 6a is protected with the resin layer 8, and the insulation between the electronic component 6a and the shielding member 3 can be improved by the insulator 7.

### Sixth Embodiment

### 1 Structure

In the radio frequency module 1c according to a sixth embodiment, a height H1 in the first direction D1 of the shielding member 3 from the first main surface 21 of the mounting board 2 is higher than the height of any other electronic component disposed on the first main surface 21 of the mounting board 2.

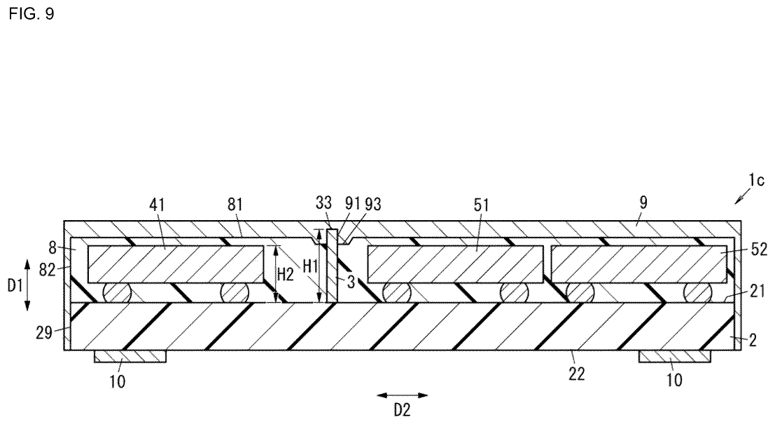

Specifically, as illustrated in FIG. 9, the height H1 in the first direction D1 of the shielding member 3 from the first main surface 21 of the mounting board 2 is greater than a height H2 in the first direction D1 of the electronic component 41 from the first main surface 21 of the mounting board 2. Here, “the height H1 in the first direction D1 of the shielding member 3 from the first main surface 21 of the mounting board 2” may be understood as the distance in the first direction D1 between the first main surface 21 of the mounting board 2 and one end 33 not in contact with the mounting board 2 of the end portions of the shielding member 3 arranged in the first direction D1. In addition, “the height H2 in the first direction D1 of the electronic component 41 from the first main surface 21 of the mounting board 2” may be understood as the distance in the first direction D1 between the first main surface 21 of the mounting board 2 and the main surface opposite to the main surface facing the first main surface 21 of the mounting board 2 of the plurality of main surfaces of the electronic component 41. Here, the height H2 in the first direction D1 of the electronic component 41 from the first main surface 21 of the mounting board 2 is equal to or greater than the height in the first direction D1 of the electronic component 51 from the first main surface 21 of the mounting board 2 and is equal to or greater than the height in the first direction D1 of the electronic component 52 from the first main surface 21 of the mounting board 2. That is, the height H1 in the first direction D1 of the shielding member 3 from the first main surface 21 of the mounting board 2 is greater than the height in the first direction D1 of any component disposed on the first main surface 21 of the mounting board 2 from the first main surface 21 of the mounting board 2. Accordingly, the effect of isolation between the electronic component 41 and the electronic component 51 due to the shielding member 3 is improved.

In the radio frequency module 1c according to the sixth embodiment, the external shielding electrode 9 has a recessed portion 91 in a surface facing the first main surface 21 of the mounting board 2. One end 33 not in contact with the mounting board 2 of two end portions of the shielding member 3 arranged in the first direction D1 is disposed in the recessed portion 91 of the external shielding electrode 9. As a result, since the adhesiveness between the external shielding electrode 9 and the shielding member 3 is improved, the external shielding electrode 9 and the ground electrode 23 are electrically connected to each other via the shielding member 3. Accordingly, the electromagnetic shielding effect of the external shielding electrode 9 is improved.

### 2 Effects

In the radio frequency module 1c according to the sixth embodiment, the height H1 in the first direction D1 of the shielding member 3 with respect to the first main surface 21 of the mounting board 2 is greater than the height H2 in the first direction D1 of any component, other than the shielding member 3, that is disposed on the first main surface 21 of the mounting board 2 with respect to the first main surface 21 of the mounting board 2. As a result, since the adhesiveness between the shielding member 3 and the external shielding electrode 9 is improved in the radio frequency module 1c according to the sixth embodiment, the shielding performance of the external shielding electrode 9 is improved.

### Seventh Embodiment

### 1 Structure

In the radio frequency module 1c according to a seventh embodiment, the height H1 of the shielding member 3 from the mounting board 2 is smaller than the height of any other electronic component disposed on the first main surface 21 of the mounting board 2.

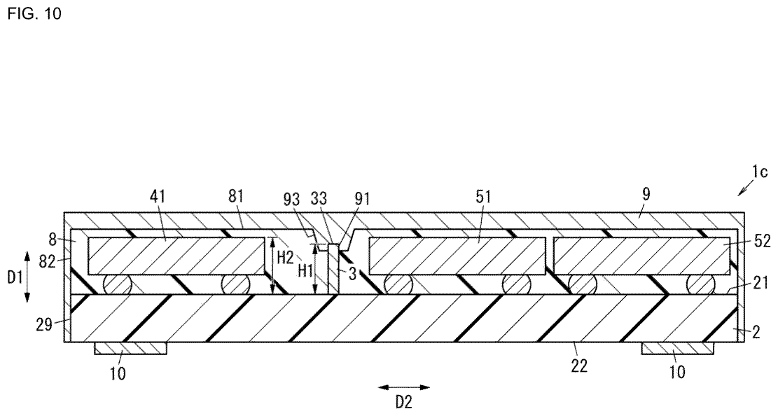

Specifically, as illustrated in FIG. 10, the height H1 in the first direction D1 of the shielding member 3 from the first main surface 21 of the mounting board 2 is smaller than the height H2 in the first direction D1 of the electronic component 41 from the first main surface 21 of the mounting board 2. As a result, the height H1 in the first direction D1 of the shielding member 3 from the first main surface 21 of the mounting board 2 is smaller than the height in the first direction D1 of any component disposed on the first main surface 21 of the mounting board 2 from the first main surface 21 of the mounting board 2.

In the radio frequency module 1c according to the seventh embodiment, the external shielding electrode 9 has a raised portion 93 on a surface facing the first main surface 21 of the mounting board 2, and the raised portion 93 includes the recessed portion 91. One end 33 not in contact with the mounting board 2 of two end portions of the shielding member 3 arranged in the first direction D1 is disposed in the recessed portion 91 of the external shielding electrode 9. Accordingly, isolation between the electronic component 41 and the electronic component 51 can be ensured by the shielding member 3 and the external shielding electrode 9.

In addition, in the radio frequency module 1c according to the seventh embodiment, the height H1 in the first direction D1 of the shielding member 3 from the first main surface 21 of the mounting board 2 is smaller than the height of any other electronic component disposed on the first main surface 21 of the mounting board 2. Accordingly, the thickness in the first direction D1 of the radio frequency module 1c can be reduced. Accordingly, the radio frequency module 1c can be downsized. In addition, upon the radio frequency module 1c being manufactured, the shielding member 3 does not need to be polished, and the height of the shielding member 3 does not need to be adjusted to match the heights of the electronic components 41, 51, and 52. Accordingly, the manufacturing cost of the radio frequency module 1c can be reduced.

### 2 Effects

In the radio frequency module 1c according to the seventh embodiment, the external shielding electrode 9 has the raised portion 93 facing the first main surface 21 of the mounting board 2. The recessed portion 91 of the external shielding electrode 9 is located in the raised portion 93. As a result, since the adhesiveness and the connection reliability between the shielding member 3 and the external shielding electrode 9 are improved in the radio frequency module 1c according to the seventh embodiment, the shielding performance of the external shielding electrode 9 is improved.

In addition, the radio frequency module 1c according to the seventh embodiment, the height H1 in the first direction D1 of the shielding member 3 with respect to the first main surface 21 of the mounting board 2 is smaller than the height H2 in the first direction D1 of any one component, other than the shielding member 3, that is mounted on the first main surface 21 of the mounting board 2 with respect to the first main surface 21 of the mounting board 2. As a result, in the radio frequency module 1c according to the seventh embodiment, the heights of the shielding members 3 can be equalized among the plurality of radio frequency modules 1c including electronic components with different heights. Accordingly, the manufacturing cost of the radio frequency module 1c can be reduced.

### Eighth Embodiment

In the radio frequency module 1c according to an eighth embodiment, as in the radio frequency module 1c according to the seventh embodiment, the height H1 of the shielding member 3 from the mounting board 2 is smaller than the height of any other electronic component disposed on the first main surface 21 of the mounting board 2.

In addition, in the radio frequency module 1c according to the eighth embodiment, the thickness in the first direction D1 of the external shielding electrode 9 has high uniformity. As a result, the external shielding electrode 9 has a recessed portion 94.

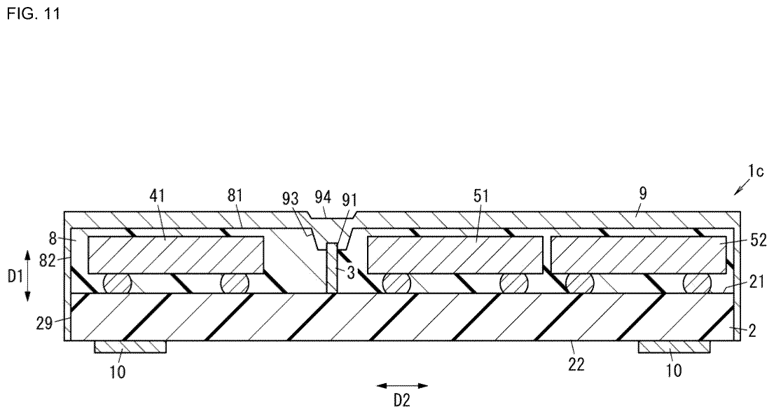

Specifically, as illustrated in FIG. 11, the external shielding electrode 9 has the raised portion 93 on a surface facing the first main surface 21 of the mounting board 2. In addition, the external shielding electrode 9 has the recessed portion 94 that overlaps the raised portion 93 in the first direction D1.

In the radio frequency module 1c according to the eighth embodiment, the external shielding electrode 9 does not have a locally thick portion in the first direction D1. Accordingly, the material of the external shielding electrode 9 can be reduced without the electromagnetic shielding effect of the external shielding electrode 9 being reduced. In addition, since the thickness in the first direction D1 of the external shielding electrode 9 has high uniformity in the radio frequency module 1c according to the eighth embodiment, the external shielding electrode 9 can be easily formed by vacuum deposition or sputtering.

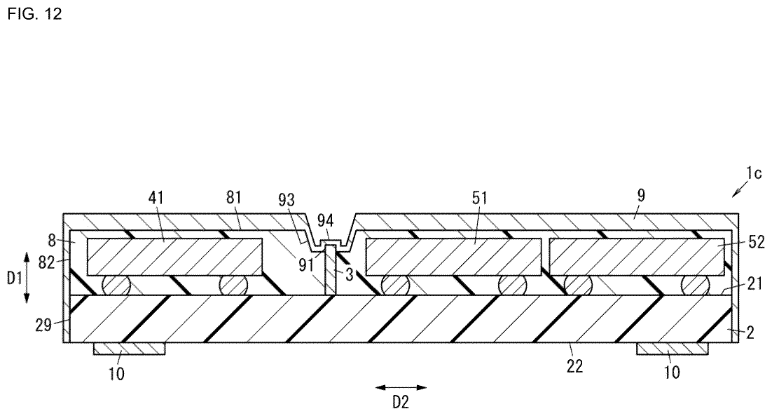

In addition, in the radio frequency module 1c according to the eighth embodiment, the thickness in the first direction D1 of the external shielding electrode 9 may be reduced, as illustrated in FIG. 12.

### MODIFICATIONS

Modifications of the embodiments will be described below.

Each of the radio frequency modules 1 according to the first to eight embodiments may include the plurality of power amplifiers 151. At least one of the plurality of power amplifiers 151 is included in, for example, the electronic component 41. Similarly, each of the radio frequency modules 1 according to the first to eighth embodiments may include the plurality of low-noise amplifiers 152. At least one of the plurality of low-noise amplifiers 152 is included in, for example, the electronic component 51.

In addition, each of the radio frequency modules 1 according to the first to eighth embodiments may include the plurality of power amplifiers 151 instead of the low-noise amplifier 152. At least one of the plurality of power amplifiers 151 is included in the electronic component 41, and at least another of the other power amplifiers 151 is included in the electronic component 51. In this structure, the radio frequency module 1 that is a transmission module can improve isolation between the plurality of power amplifiers 151.

In addition, in each of the radio frequency modules 1 according to the first to eighth embodiments, the electronic component 6 may be any non-capacitor element connected to the ground electrode 23, such as an inductor or an IC including a switch. Similarly, each of the electronic components 6a and 6b may be any element not connected to the ground electrode 23, such as a filter, an inductor, or a capacitor.

In addition, in each of the radio frequency modules 1 according to the first to eighth embodiments, one or more electronic components may be disposed on the second main surface 22 of the mounting board 2.

In addition, in the radio frequency module 1 according to the second or fifth embodiment, the shielding member 3 does not need to be connected to the ground electrode 23. Also in this case, the shielding member 3 and the external shielding electrode 9 also achieve electromagnetic shielding effects.

In addition, in each of the radio frequency modules 1 according to the fourth to eighth embodiments, the external shielding electrode 9 may be connected to the ground electrode 23 via the outer peripheral surface 29 of the mounting board 2.

### ASPECTS

A radio frequency module (1 to 1c) according to a first aspect include a mounting board (2), a first component (6 to 6b), and a shielding member (3). The mounting board (2) includes a first main surface (21) and a second main surface (22). The first component (6 to 6b) is disposed on the first main surface (21) of the mounting board (2). The shielding member (3) is disposed on the first main surface (21) of the mounting board (2). The first component (6 to 6b) is in contact with the shielding member (3).

Since the first component (6 to 6b) and the shielding member (3) can be disposed close to each other in plan view in a thickness direction (D1) of the mounting board (2) in the radio frequency module (1 to 1c) according to the aspect described above, the area of the mounting board (2) can be reduced. Accordingly, the radio frequency module (1 to 1c) can be downsized.

In the radio frequency module (1, 1c) according to a second aspect, the first component (6) according to the first aspect includes an electrode (61) connected to the mounting board (2) in the first aspect. The shielding member (3) is in contact with the electrode (61) of the first component (6).

In the radio frequency module (1, 1c) according to the aspect described above, degradation of the characteristics of the radio frequency module due to parasitic capacitance generated between the first component (6) and the shielding member (3) can be reduced.

In the radio frequency module (1, 1c) according to a third aspect, the mounting board (2) includes a ground electrode (23) according to the second aspect. The electrode (61) of the first component (6) is connected to the ground electrode (23). The shielding member (3) is in contact with an electrode (24) of the mounting board (2) connected to the ground electrode (23).

In the radio frequency module (1, 1c) according to the aspect described above, the electrode (61) of the first component (6) can be connected to the ground electrode (23) via the shielding member (3). Accordingly, the connectivity between the electrode (61) of the first component (6) and the ground electrode (23) is improved.

In the radio frequency module (1a, 1c) according to a fourth aspect, the shielding member (3) includes the main surface (31) facing the first component (6a) in the first aspect. An insulator (7) is disposed on the main surface (31) of the shielding member (3).

In the radio frequency module (1a, 1c) according to the aspect described above, the first component (6a) can be easily disposed in contact with the shielding member (3) because the first component (6a) and the shielding member (3) can be insulated from each other. Accordingly, the radio frequency module (1a, 1c) can be easily downsized.

The radio frequency module (1c) according to a fifth aspect further includes a resin layer (8) that covers the mounting board (2) and the first component (6a) in the fourth aspect. The material of the insulator (7) differs from the material of the resin layer (8). At least a portion of the insulator (7) is located between the shielding member (3) and the first component (6a).

In the radio frequency module (1c) according to the aspect described above, the first component (6a) is protected by the resin layer (8) and insulation between the first component (6a) and the shielding member (3) can be improved by the insulator (7).

The radio frequency module (1 to 1c) according to a sixth aspect further includes a second component (41) and a third component (51) disposed on the first main surface (21) of the mounting board (2) in any one of the first to fifth aspects. The shielding member (3) is disposed between the second component (41) and the third component (51). At least one of the second component (41) and the third component (51) is a power amplifier (151) that amplifies a transmission signal.

In the radio frequency module (1 to 1c) according to the aspect described above, isolation between the second component (41) and the third component (51) is improved.

The radio frequency module (1c) according to a seventh aspect further includes an external shielding electrode (9) that covers the first main surface (21) of the mounting board (2) in any one of the first to sixth aspects. The mounting board (2) includes the ground electrode (23) connected to the shielding member (3). The shielding member (3) is in contact with the external shielding electrode (9).

In the radio frequency module (1c) according to the aspect described above, the external shielding electrode (9) can be connected to the ground electrode (23) via the shielding member (3). Accordingly, the noise resistance of the radio frequency module (1c) is improved.

In the radio frequency module (1c) according to an eighth aspect, the external shielding electrode (9) includes a recessed portion (91) facing the first main surface (21) of the mounting board (2) in the seventh aspect. The shielding member (3) is in contact with the recessed portion (91) of the external shielding electrode (9).

In the radio frequency module (1c) according to the aspect described above, the shielding performance of the external shielding electrode (9) is improved because the contact area between the shielding member (3) and the external shielding electrode (9) is large.

In the radio frequency module (1c) according to a ninth aspect, a height (H1) in the first direction (D1) of the shielding member (3) with respect to the first main surface (21) of the mounting board (2) is greater than a height (H2) in the first direction (D1) of any component, other than the shielding member (3), that is disposed on the first main surface (21) of the mounting board (2) with respect to the first main surface (21) of the mounting board (2) in the seventh or eighth aspect. The first direction (D1) is the thickness direction of the mounting board (2).

Since the adhesiveness between the shielding member (3) and the external shielding electrode (9) is improved in the radio frequency module (1c) according to the aspect described above, the shielding performance of the external shielding electrode (9) is improved.

In the radio frequency module (1c) according to a tenth aspect, the external shielding electrode (9) has a raised portion (93) facing the first main surface (21) of the mounting board (2) in the eighth or ninth aspect. The recessed portion (91) of the external shielding electrode (9) is located in the raised portion (93).

Since the adhesiveness between the shielding member (3) and the external shielding electrode (9) is improved in the radio frequency module (1c) according to the aspect described above, the shielding performance of the external shielding electrode (9) is improved.

In the radio frequency module (1c) according to an eleventh aspect, the height (H1) in the first direction (D1) of the shielding member (3) with respect to the first main surface (21) of the mounting board (2) is smaller than the height (H2) in the first direction (D1) of any one component, other than the shielding member (3), that is disposed on the first main surface (21) of the mounting board (2) with respect to the first main surface (21) of the mounting board (2) in the tenth aspect. The first direction (D1) is the thickness direction of the mounting board (2).

In the radio frequency module (1c) according to the aspect described above, the heights of the shielding members (3) can be equalized among the plurality of radio frequency modules (1c) including electronic components with different heights. Accordingly, the manufacturing cost of the radio frequency module (1c) can be reduced.

A communication device (100) according to a twelfth aspect includes the radio frequency module (1 to 1c) according to any one of the first to eleventh aspects and a signal processing circuit (17) connected to the radio frequency module (1 to 1c).

In the communication device (100) according to the aspect described above, downsizing and high integration of the communication device (100) can be achieved by downsizing the radio frequency module (1).

What is claimed is:

1. A radio frequency module comprising:
a mounting board having a first main surface and a second main surface;
a first component disposed on the first main surface of the mounting board; and
a shielding member disposed on the first main surface of the mounting board,
wherein the first component is in contact with the shielding member.

2. The radio frequency module according to claim 1,
wherein the first component includes an electrode connected to the mounting board, and
the shielding member is in contact with the electrode of the first component.

3. The radio frequency module according to claim 2,
wherein the mounting board includes a ground electrode,
the electrode of the first component is connected to the ground electrode, and
the shielding member is in contact with an electrode of the mounting board connected to the ground electrode.

4. The radio frequency module according to claim 1,
wherein the shielding member has a main surface facing the first component, and
an insulator is disposed on the main surface of the shielding member.

5. The radio frequency module according to claim 4, further comprising:
a resin layer that covers the mounting board and the first component,
wherein a material of the insulator differs from a material of the resin layer, and
at least a portion of the insulator is located between the shielding member and the first component.

6. The radio frequency module according to claim 1, further comprising:
a second component and a third component that are disposed on the first main surface of the mounting board,
wherein the shielding member is disposed between the second component and the third component, and
at least one of the second component and the third component is a power amplifier that amplifies a transmission signal.

7. The radio frequency module according to claim 1, further comprising:
an external shielding electrode that covers the first main surface of the mounting board,
wherein the mounting board includes a ground electrode connected to the shielding member, and
the shielding member is in contact with the external shielding electrode.

8. The radio frequency module according to claim 7,
wherein the external shielding electrode has a recessed portion facing the first main surface of the mounting board, and
the shielding member is in contact with the recessed portion of the external shielding electrode.

9. The radio frequency module according to claim 8,
wherein a height in a first direction of the shielding member with respect to the first main surface of the mounting board is greater than a height in the first direction of any component, other than the shielding member, that is disposed on the first main surface of the mounting board with respect to the first main surface of the mounting board, the first direction being a thickness direction of the mounting board.

10. The radio frequency module according to claim 8,
wherein the external shielding electrode has a raised portion facing the first main surface of the mounting board, and
the recessed portion of the external shielding electrode is located in the raised portion.

11. The radio frequency module according to claim 10,
wherein a height in a first direction of the shielding member with respect to the first main surface of the mounting board is smaller than a height in the first direction of any one component, other than the shielding member, that is disposed on the first main surface of the mounting board with respect to the first main surface of the mounting board, the first direction being a thickness direction of the mounting board.

12. A communication device comprising:
the radio frequency module according to claim 3; and
a signal processing circuit connected to the radio frequency module.

13. A communication device comprising:
the radio frequency module according to claim 4; and
a signal processing circuit connected to the radio frequency module.

14. A communication device comprising:
the radio frequency module according to claim 5; and
a signal processing circuit connected to the radio frequency module.

15. A communication device comprising:
the radio frequency module according to claim 6; and
a signal processing circuit connected to the radio frequency module.

16. A communication device comprising:
the radio frequency module according to claim 7; and
a signal processing circuit connected to the radio frequency module.

17. A communication device comprising:
the radio frequency module according to claim 8; and
a signal processing circuit connected to the radio frequency module.

18. A communication device comprising:
the radio frequency module according to claim 9; and
a signal processing circuit connected to the radio frequency module.

19. A communication device comprising:
the radio frequency module according to claim 10; and
a signal processing circuit connected to the radio frequency module.

20. A communication device comprising:
the radio frequency module according to claim 11; and
a signal processing circuit connected to the radio frequency module.
